(19) United States
(12) Patent Application Publication
(10) Pub. No.: US 2016/0377692 A1
(43) Pub. Date: Dec. 29, 2016

(54) RETRACTABLE MR COIL DEVICE

(71) Applicants: Peter Gall, Buckenhof (DE); Andreas Greiser, Erlangen (DE); Martin Harder, Nurnberg (DE); Katharina Hesels, Erlangen (DE); Hans-Peter Hollenbach, Eggolsheim (DE); Esther Raithel, Dormitz (DE); Stephan Zink, Erlangen (DE)

(72) Inventors: Peter Gall, Buckenhof (DE); Andreas Greiser, Erlangen (DE); Martin Harder, Nurnberg (DE); Katharina Hesels, Erlangen (DE); Hans-Peter Hollenbach, Eggolsheim (DE); Esther Raithel, Dormitz (DE); Stephan Zink, Erlangen (DE)

(21) Appl. No.: 15/190,866

(22) Filed: Jun. 23, 2016

(30) Foreign Application Priority Data
Jun. 24, 2015 (DE) 102015211719.7

(51) Int. Cl. G01R 33/34; G01R 33/30

(52) U.S. Cl. CPC G01R 33/34084; G01R 33/30

(57) ABSTRACT

A magnetic resonance coil apparatus, a magnetic resonance apparatus and a method for handling a magnetic resonance coil apparatus are provided. The magnetic resonance coil apparatus includes a first coil unit and a second coil unit. The first coil unit and the second coil unit are configured to rotate about a longitudinal axis relative to one another.

### CROSS-REFERENCE TO RELATED APPLICATIONS

The present patent document claims the benefit of DE 102015211719.7, filed on Jun. 24, 2015, which is hereby incorporated by reference in its entirety.

### TECHNICAL FIELD

The present embodiments relate to a magnetic resonance coil apparatus, a magnetic resonance apparatus, and a method for handling a magnetic resonance coil apparatus.

### BACKGROUND

Imaging methods represent important tools in medical technology. In clinical cross-sectional imaging, magnetic resonance tomography (MRT) is characterized by high and variable soft tissue contrasts. To create an image using magnetic resonance tomography, one or a number of magnetic resonance coil apparatuses are typically used to send and/or receive radio-frequency (RF) signals.

A magnetic resonance apparatus typically has a body coil that is integrated into the magnetic resonance apparatus in a fixed manner and primarily serves to send RF signals. The body coil may also be used to receive RF signals. With the use of local magnetic resonance coil apparatuses, in addition to the body coil, the simplicity of the positioning of an examination object (e.g., a patient) is an important aspect for optimizing the operational procedure during an MRT examination, and thus ultimately for minimizing the examination duration.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a magnetic resonance coil apparatus that may be used in a simple and space-saving manner (e.g., in a cylindrical magnetic resonance coil apparatus), and may be used for measuring the outer extremities of a patient (e.g., such as arms and legs) is provided.

The magnetic resonance coil apparatus includes a first coil unit and a second coil unit. At least one of the coil units is arranged so as to be able to rotate about a longitudinal axis. For example, the coil units are configured to rotate relative to one another about the longitudinal axis. The orientation of the longitudinal axis, which may be a shared longitudinal axis of the two coil units, may be derived from the shape of the coil units. The rotation may take place in a peripheral direction about the longitudinal axis.

The magnetic resonance coil apparatus may be a local coil (e.g., a local coil may be arranged in close proximity to a body part to be examined). Contrary to a body coil that is installed in a magnetic resonance apparatus in a fixed manner, a local coil may be freely positioned in a patient support area.

Dividing the magnetic resonance apparatus into two units (e.g., the first and second coil unit) allows for greater flexibility in arrangement and shape. The geometrical adaptability of the magnetic resonance coil apparatus may be further increased by rotation about the longitudinal axis. In this way, a relative movement of the coil units in relation to one another may be performed (e.g., the first coil unit may be transferred from an original angular position into another angular position relative to the second coil unit). Selecting the angular position enables the magnetic resonance coil apparatus to be changed in terms of compactness such that space-saving configurations (e.g., referred to as operating states) may be enabled. For example, the coil units may be pushed together.

The magnetic resonance coil apparatus is configured to, by rotating at least one of the coil units about the longitudinal axis, change between an open operating state and a closed operating state.

An open operating state may be configured to position an examination object in a receiving zone of the magnetic resonance apparatus, whereas a closed operating state may be configured to send excitation signals and/or receive resonance signals.

Specifically, with an open operating state, the components of the magnetic resonance apparatus may be arranged to be compact in accordance with the present embodiments such that a fault-free operational procedure is inter alia possible.

A larger circular arc of a cylindrical volume is covered by the coil units in a closed operating state than in an open operating state.

The smaller coverage of the cylindrical volume in the open operating state allows for good accessibility for a possible positioning of an examination object within the cylindrical volume. In a closed state, the cylindrical volume may be completely enclosed (e.g., the covered circular arc of the cylindrical volume covers 360°). One part may, however, not be covered (e.g., the covered circular arc of the cylindrical volume may cover less than 360°). For example, a coverage area of less than 360° may be adequate for the performance of an MRT examination.

For rotation of the coil units, the magnetic resonance coil apparatus may have a rotation guide unit. The rotation guide unit may have roller bearings and/or slide bearings such that the magnetic resonance coil apparatus may be operated in as comfortable and effortless a manner as possible. Further, guide elements (e.g., rails, grooves, springs etc.) are known to the person skilled in the art.

The coil units may be arranged concentrically about the longitudinal axis (e.g., the coil units have geometrical structures with a shared center point and/or a shared center line). The first coil unit may be pushed into the second coil unit and vice versa.

The first coil unit may have a first cylindrical partial shell, and the second coil unit may have a second cylindrical partial shell. One of the two partial shells is arranged internally relative to the other of the two partial shells such that the other of the two partial shells is arranged externally. The partial shell arranged internally may have a smaller spatial distance from a concentric longitudinal axis than the partial shell arranged externally. A space-saving pushing of the coil units into one another and/or a retraction of the one coil unit into the other coil unit is thus particularly easy to realize.

A partial shell may include half of a circular cylinder (e.g., a circular segment of 180°) so that the partial shell is embodied as a half-shell. Moldings that deviate from a half-shell may also be provided. In one embodiment, the two partial shells may cover areas of a circular cylinder of different sizes (e.g., the first cylindrical partial shell covers a circular segment of 160°, and the second cylindrical partial shell covers a circular segment of 200°).

For example, the partial shells may be arranged concentrically to the longitudinal axis. Therefore, all points that lie on at least one surface of a partial shell may have the same distance from the longitudinal axis. This distance remains constant during a rotation about this longitudinal axis.

In the open operating state, the surfaces of the cylindrical partial shells may overlap one another. In this way, directly opposing surfaces of the partial shells may be at a distance in the overlapping area in order to be able to rotate the partial shells relative to one another. The distance between the opposing surfaces may be less than 20 mm (e.g., less than 10 mm, less than 5 mm, and/or less than 2 mm). A space-saving design of the magnetic resonance coil apparatus is thus enabled.

One embodiment provides that the internally arranged partial shell has an outer surface, and the other of the two partial shells has an inner surface. In an open operating state, in an overlapping area of the partial shells, the outer surface of the internally arranged partial shell is in parallel to the inner surface of the other of the two partial shells (e.g., the corresponding surfaces are molded so as to match one another). The contours of the partial shells may engage into one another with an accurate fit.

The internally arranged partial shell may have an outside diameter, and the other of the two partial shells may have an inside diameter, where the outside diameter of the internally arranged partial shell is at most as large as the inside diameter of the other of the two partial shells so that a fault-free rotation may be provided.

The difference in the diameter of the opposing surfaces (e.g., surfaces that face one another) may amount to less than 40 mm (e.g., less than 20 mm, 10 mm, and/or 4 mm) in order to restrict the space requirement of the magnetic resonance coil apparatus to a minimum.

One embodiment provides that the coil units are provided, in a closed operating state, to cause an interlock of the coil units (e.g., by a relative movement between the first coil unit and the second coil unit in the direction of the longitudinal axis). The interlock may be performed by a linear (e.g., straight-lined) movement of at least one of the coil units. The interlock of the coil units may provide reliable operation in the closed operating state.

The magnetic resonance coil apparatus may establish an electrical and/or mechanical connection between the coil units when the coil units are interlocked. The mechanical connection provides a stable configuration for the performance of an MRT examination. The electrical connection enables signals (e.g., magnetic resonance signals) to be exchanged between the magnetic resonance coil apparatus and a magnetic resonance apparatus. For communication between the two coil units and a magnetic resonance apparatus, a separate signal cable is not required for the individual coil units (e.g., one single cable is sufficient for both coil units).

For example, the magnetic resonance coil apparatus may include a linear guide unit for the relative movement of the coil units in the direction of the longitudinal axis. The linear guide unit may have roller bearings and/or slide bearings such that the magnetic resonance coil apparatus may be operated in as user-friendly and effortless a manner as possible. Further guide elements (e.g., rails, grooves etc.) are known to the person skilled in the art.

The coil units may have connecting elements to mechanically and/or electrically connect the coil units (e.g., in a closed operating state). These connecting elements may be support surfaces and/or electrical contacts that are geometrically matched to each other.

For example, the connecting elements may be in an annular manner and arranged on the ends of the coil units in the direction of the longitudinal axis. A simple connection mechanism may be provided without hindering the rotary motion for opening and closing the magnetic resonance coil apparatus.

The first coil unit may have at least one RF coil, and/or the second coil unit may have at least one RF coil such that radio-frequency electromagnetic signals may be sent and/or received by the magnetic resonance coil apparatus.

A magnetic resonance apparatus with a magnetic resonance coil apparatus of one or more of the present embodiments is also provided. The advantages of the magnetic resonance apparatus essentially correspond to the advantages of the magnetic resonance coil apparatus, which are explained above in detail. Features, advantages, or alternative embodiments mentioned herein may also be applied to the other subject matter and vice versa.

For example, a magnetic resonance apparatus, in which one of the two coil units is arranged in a fixed-location manner, is provided. For example, the first coil unit may be assembled in a fixed manner on a patient support apparatus included in the magnetic resonance apparatus. The second coil unit may then be retracted into the first coil unit by rotation in an opened operating state.

A method for handling a magnetic resonance coil apparatus, whereby an examination object is positioned in a receiving zone of the magnetic resonance apparatus in an open operating state, at least one of the coil units is rotated in order to produce a closed operating state, and a linear movement of at least one of the coil units causes the coil units to interlock, is also provided.

Before the aforementioned method acts, the magnetic resonance coil apparatus may be assembled on a magnetic resonance apparatus. In the closed operating state, an MRT examination may then be performed. This method allows for a simple, user-friendly and rapid operational procedure.

### BRIEF DESCRIPTION OF THE DRAWINGS

FIG. 1 shows a front view of a schematic representation of a magnetic resonance coil apparatus in an open operating state according to an embodiment.

FIG. 2 shows a side view of a schematic representation of a magnetic resonance coil apparatus in an open operating state according to an embodiment.

FIG. 3 shows a front view of a schematic representation of a magnetic resonance coil apparatus in a half-open operating state according to an embodiment.

FIG. 4 shows a side view of a schematic representation of a magnetic resonance coil apparatus in a half-open operating state according to an embodiment.

FIG. 5 shows a front view of a schematic representation of a magnetic resonance apparatus in a closed operating state according to an embodiment.

FIG. 6 shows a side view of a schematic representation of a magnetic resonance apparatus in a closed operating state according to an embodiment.

FIG. 7 shows a front view of a schematic representation of a magnetic resonance apparatus in a closed and interlocked operating state according to an embodiment.

FIG. 8 shows a side view of a schematic representation of a magnetic resonance apparatus in a closed and interlocked operating state according to an embodiment.

FIG. 9 shows a three-dimensional schematic representation of a magnetic resonance coil apparatus in a closed and interlocked operating state according to an embodiment.

FIG. 10 shows a three-dimensional schematic representation of a magnetic resonance coil apparatus in a closed operating state according to an embodiment.

FIG. 11 shows a side view of a further schematic representation of a magnetic resonance coil apparatus in a closed operating state according to an embodiment.

FIG. 12 shows a further three-dimensional schematic representation of a magnetic resonance coil apparatus in a closed and interlocked operating state according to an embodiment.

FIG. 13 shows a side view of a further schematic representation of a magnetic resonance coil apparatus in a closed and interlocked operating state according to an embodiment.

FIG. 14 shows a schematic representation of a magnetic resonance apparatus according to an embodiment.

FIG. 15 shows a block diagram of a method according to an embodiment.

### DETAILED DESCRIPTION

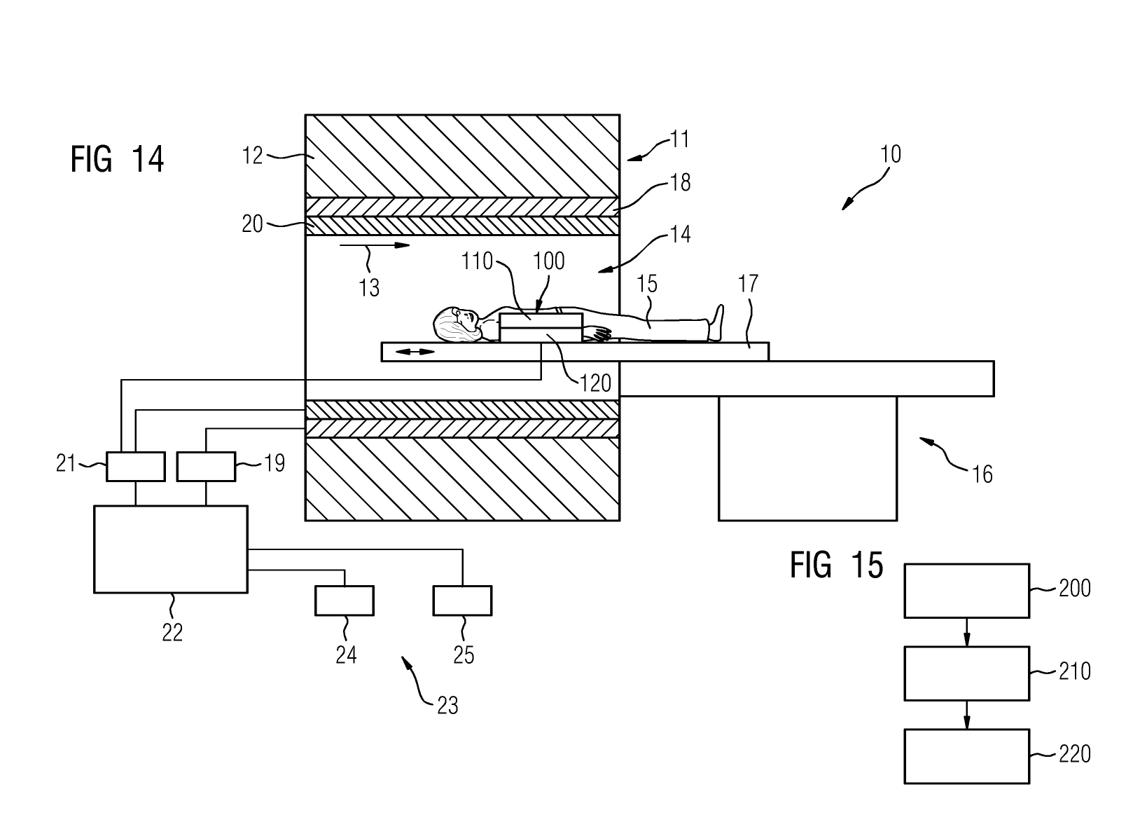

FIG. 14 shows a schematic representation of a magnetic resonance apparatus 10 with a magnetic resonance coil apparatus 100. The magnetic resonance apparatus 10 includes a magnet unit 11 having a superconducting main magnet 12 for generating a powerful (e.g., constant) main magnetic field 13. The magnetic resonance apparatus 10 also includes a patient receiving zone 14 for receiving a patient 15. The patient receiving zone 14 is cylindrical in the present exemplary embodiment and is cylindrically surrounded by the magnet unit 11 in a peripheral direction. An embodiment of the patient receiving zone 14 deviating from a cylindrical design may also be provided. The patient 15 may be introduced into the patient receiving zone 14 by a patient support apparatus 16 of the magnetic resonance apparatus 10. The patient support apparatus 16 includes a patient couch 17 that is configured to be movable within the patient receiving zone 14.

The magnet unit 11 also includes a gradient coil unit 18 for generating magnetic field gradients used for position encoding during imaging. The gradient coil unit 18 is controlled by a gradient control unit 19 of the magnetic resonance apparatus 10. The magnet unit 11 further includes a radio frequency antenna unit 20 that is, for example, a body coil that is integrated into the magnetic resonance apparatus 10 in a fixed manner. The radio frequency antenna unit 20 is configured to excite atomic nuclei that become established in the main magnetic field 13 generated by the main magnet 12. The radio frequency antenna unit 20 is controlled by a radio frequency antenna control unit 21 of the magnetic resonance apparatus 10 and radiates radio frequency magnetic resonance sequences into an examination space that is substantially formed by a patient receiving zone 14 of the magnetic resonance apparatus 10. The radio frequency antenna unit 20 is also configured for receiving magnetic resonance signals.

The magnetic resonance apparatus 10 includes a system control unit 22 for controlling the main magnet 12, the gradient coil unit 19, and the radio frequency antenna control unit 21. The system control unit 22 centrally controls the magnetic resonance apparatus 10 (e.g., performing a predetermined imaging gradient echo sequence). The system control unit 22 also includes an evaluation unit (not shown in greater detail) for evaluating medical image data that is acquired during the magnetic resonance examination. The magnetic resonance apparatus 10 includes a user interface 23 connected to the system control unit 22. Control information (e.g., imaging parameters) and reconstructed magnetic resonance images may be displayed on a display unit 24 (e.g., on at least one monitor) of the user interface 23 for a medical operator. The user interface 23 includes an input unit 25 by which information and/or parameters may be input by the medical operator during a measurement procedure.

The magnetic resonance apparatus 10 includes a magnetic resonance coil apparatus 100 that includes a first coil unit 110 and a second coil unit 120. The first coil unit 110 and the second coil unit 120 may be rotated relative to one other. In a closed operating state, the magnetic resonance coil apparatus 100 may enclose an extremity of the patient 15 (e.g., such as a patient's arm). Here, one of the two coil units may be arranged on the patient couch 17 in a fixed-location manner (e.g., the second coil unit 120) so that, with an opening and/or a closing process only, the other of the two coil units (e.g., the first coil unit 110) rotates. The magnetic resonance coil apparatus 100 is configured like the radio frequency antenna unit 20 to excite atomic nuclei and to receive magnetic resonance signals. The magnetic coil apparatus 100 is controlled by the radio frequency antenna control unit 21.

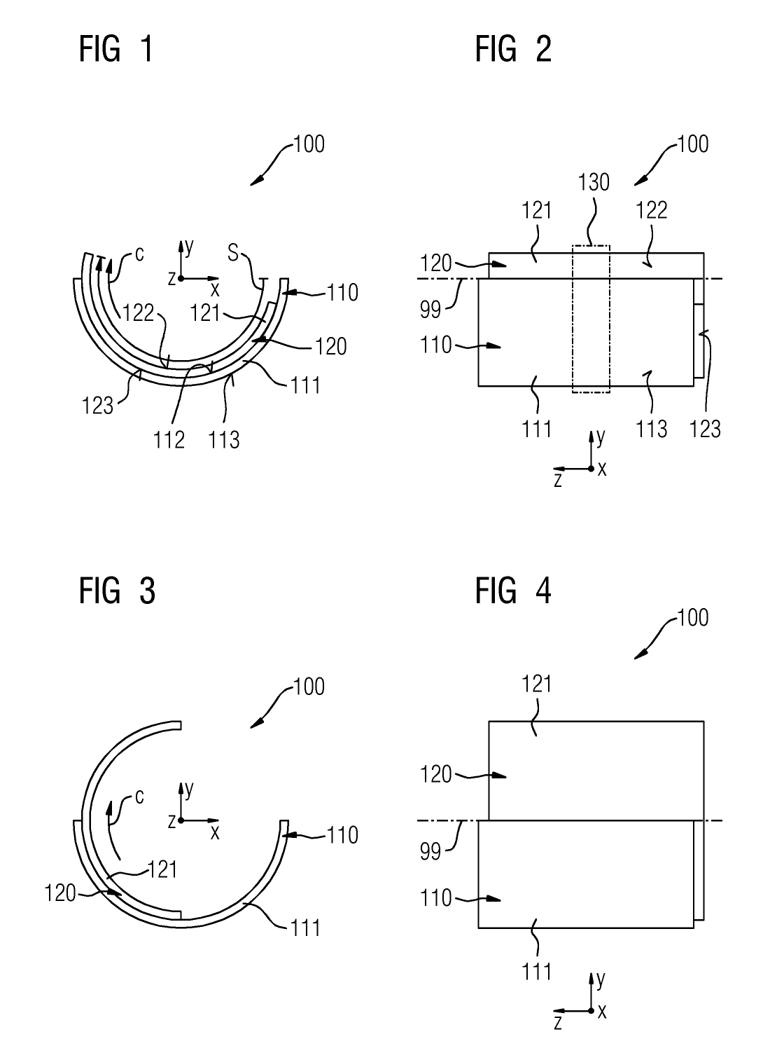

Further details of embodiments of the magnetic resonance coil apparatus 100 are shown in FIGS. 1 to 8 in two different views: A line of sight of the front views is along a longitudinal axis 99; and a line of sight of the side views is at right angles to the longitudinal axis 99. The longitudinal axis 99 is oriented in parallel to the z-axis of a coordinate system that also includes an x-axis and a y-axis. The magnetic resonance coil apparatus 100 has a first coil unit 110 and a second coil unit 120. The coil units 110, 120 are arranged to rotate relative to one another about the longitudinal axis 99 (e.g. the coil units may be moved relative to one another in a peripheral direction c).

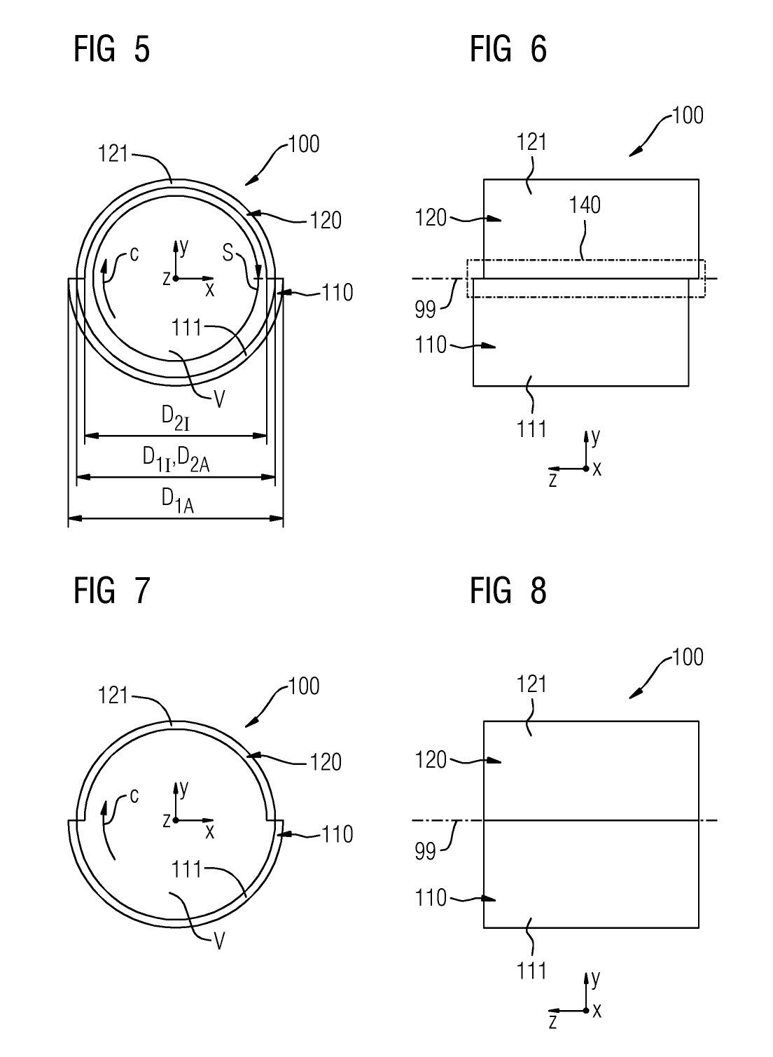

FIGS. 1 and 2 show the magnetic resonance coil apparatus 100 in an open operating state. FIGS. 3 to 6 show how, by rotating the second coil unit 120 about the longitudinal axis 99, a change from the open operating state via a half-open or half-closed operating state into a closed operating state may be provided. In this way, a larger circular arc S of a cylindrical volume V is covered in the closed operating state (e.g., as shown in FIG. 5) than in the open operating state (e.g., as shown in FIG. 1), including the volume V in the closed operating state entirely (e.g., the coverage takes place over an angular range of 360°). In one embodiment, the angular range in the closed state may be less than 360° (e.g., because a lower coverage may result in an adequate send and/or receive characteristic of the magnetic resonance coil apparatus).

In order to rotate the coil units 110, 120, the magnetic resonance coil apparatus 100 includes a rotation guide unit 130 (e.g., shown in FIG. 2). The rotation guide unit 130 may include, inter alia, bearings (e.g., slide bearings or rolling bearings) and guide elements (e.g., rails) allowing any operator of the magnetic resonance coil apparatus 100 to rotationally move the second coil unit 120 in an effortless manner.

The first coil unit 110 includes a first cylindrical partial shell (e.g., a first half-shell 111), with a first inner surface 112 and a first outer surface 113. The second coil unit 120 has a second cylindrical partial shell (e.g., a second half-shell 121), with a second inner surface 122 and a second outer surface 123.

The coil units 110, 120 are arranged concentrically around the longitudinal axis 99. For example, each of the surfaces 112, 113, 122, 123 in the peripheral direction c has a constant distance from the center line of the half-shells.

In this example, the second half-shell 121 is arranged internally relative to the first half-shell 111. In an overlapping area of the half-shells 111, 121, the outer surface 123 of the internally arranged half-shell 121 is embodied in parallel with the inner surface 112 of the other of the two half-shells 111. This parallelism avoids interfering contours on the half-shells that may hinder the rotary motion.

FIGS. 5 and 6 show one embodiment of a magnetic resonance apparatus in a closed operating state. The first cylindrical half-shell 121 has a first inside diameter D₁₁ and a first outside diameter D_{1A}. The second cylindrical half-shell 122 has a second inside diameter D₂₁ and a second outside diameter D_{2A}. The outside diameter D_{2A} of the internally arranged half-shell 121 may be (e.g., at most) as large as the inside diameter D₁₁ of the other of the two half-shells (e.g., the outer half-shell 111). In this embodiment, the diameters are shown as of equal size, and at least an infinitesimal gap between the half-shells may be provided. This provides that the half-shells may be pushed into one another.

By way of example, FIGS. 5, 6, 10, and 11 show the magnetic resonance coil apparatus 100 in a closed operating state. A relative movement between the first coil unit 110 and the second coil unit 120 in the direction of the longitudinal axis 99 may cause the coil units to interlock. In the interlocked state, as shown in FIGS. 7, 8, 12, and 13, an electrical and/or mechanical connection is established between the coil units. If only one of the two coil units 110, 120 is directly connected to a radio frequency antenna control unit 21 of a magnetic resonance apparatus 10, the other of the two coil units 110, 120 may also be actuated by the electrical connection between the coil units 110, 120.

In order to perform the relative movement for interlocking purposes, the magnetic resonance coil apparatus 100 has a linear guide unit 140 (e.g., shown in FIG. 6). Just like the rotation guide unit 130, the linear guide unit 140 may also include, inter alia, bearings (e.g., slide bearings or rolling bearings) and guide elements (e.g., rails) that allow an operator of the magnetic resonance coil apparatus 100 to move in an effortless manner.

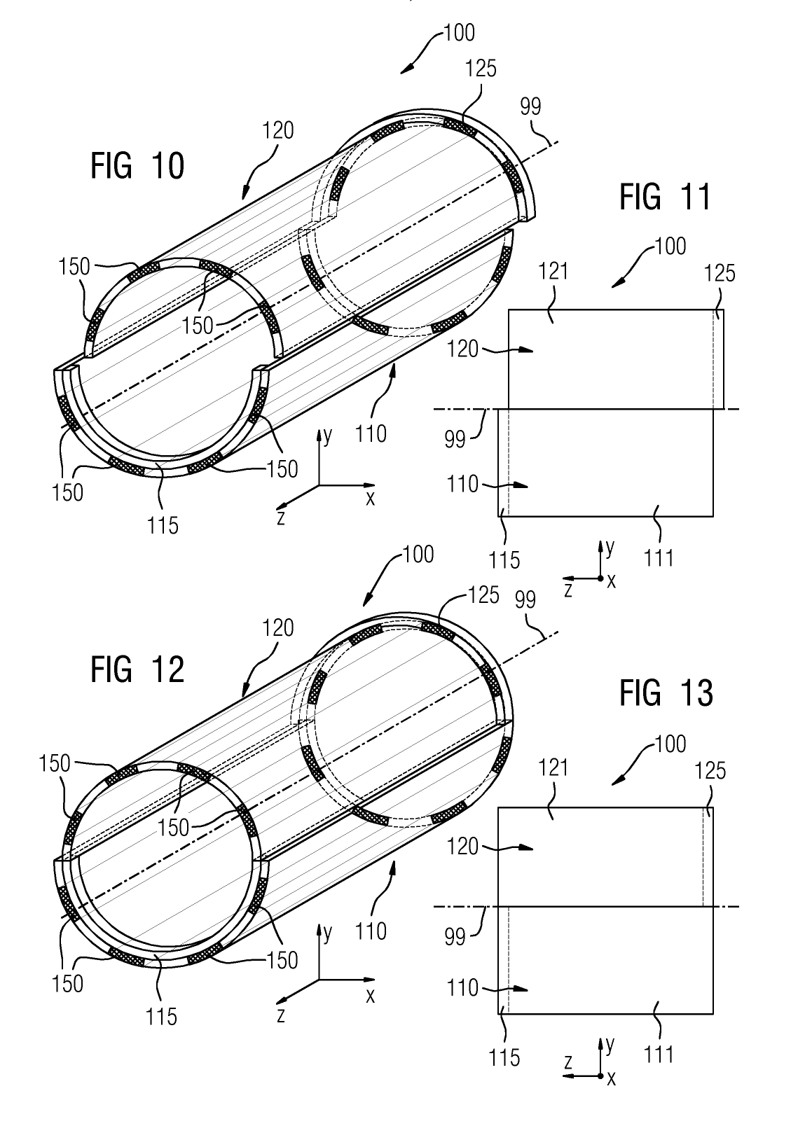

Connecting elements 115, 125 that are surrounded by the coil units 110, 120 are shown in FIGS. 10 to 13. The connecting elements 115, 125 mechanically and/or electrically connect the coil units (e.g., in particular in a closed operating state).

FIGS. 10 and 11 illustrate that, in a not yet interlocked state, there is no direct contact between the connecting element 115 of the first coil unit 110 and the second coil unit 120. The same applies to the connecting element 125 that has no contact with the first coil unit. The connecting elements may be embodied in an annular manner and are arranged on the ends of the coil units in the direction of the longitudinal axis 99.

Direct contact is established by the relative movement along the z-direction connected to the interlock (e.g., as shown in FIGS. 12 and 13). Electrical contacts that may exchange electrical signals between the coil elements 110, 120 may be arranged on the contact surface. Any mechanical structures may enable a latching of the one coil element into the other coil element.

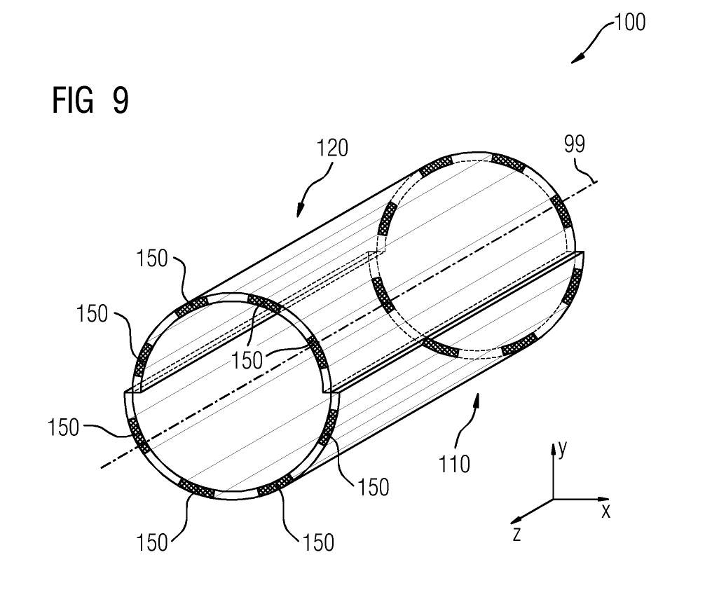

In FIGS. 9 through 12, a magnetic resonance coil apparatus 100 is shown. For example, the first and the second coil unit 110 each have a number of RF coils 150. These RF coils may be controlled by the radio frequency antenna control unit 21 of the magnetic resonance apparatus 10. The number, type, and/or shape of the RF coils may deviate from the example shown. For the sake of improved clarity, a representation of the RF coils 150 was omitted in the other figures.

A method for handling the magnetic resonance coil apparatus 100 is illustrated in FIG. 15. In act 200, an examination object 15 is positioned in a receiving zone V of the magnetic resonance apparatus 100 in an open operating state (e.g., as shown in FIG. 1). For example the examination object 15 may be an arm or a leg of a person.

In act 210, the magnetic resonance coil apparatus 100 is closed (e.g., by at least one of the coil units 110, 120 being rotated). By way of example, a transient state of this act is shown in FIGS. 3 and 4 and a final state in FIGS. 5 and 6.

A locking mechanism, locking device, and/or interlock of the coil units 110, 120 takes place with the aid of a linear movement. A locked state is shown in FIGS. 7 and 8. An MRT examination may be performed in this closed and locked operating state.

After an MRT examination, the acts are repeated in reverse order (e.g., the coil units 110, 120 are firstly unlocked, then the magnetic resonance apparatus 100 is opened so that the examination object 15 may be removed again).

Assembly of the magnetic resonance coil apparatus 100 on a magnetic resonance apparatus 10 may be performed before act 200, and disassembly may be performed after use of the magnetic resonance coil apparatus 100.

In summary, the magnetic resonance coil apparatus with a retractable coil unit of one or more of the present embodiments has a simple operational procedure (e.g., without an external folding-out of a coil unit or even removing a separable coil unit). The simple operational procedure results in a small space requirement (e.g., on a patient couch and/or in a patient environment) for the magnetic resonance coil apparatus. Storage space is not needed for the separable coil unit, which also does not have to be transported separately to and from one storage location to the magnetic resonance apparatus before and after an MRT measurement data recording. For example, the fact that this transportation is not needed reduces the risk of the magnetic resonance coil apparatus being damaged. Easier handling may save valuable time (e.g., for a patient positioning).

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A magnetic resonance coil apparatus comprising:
a first coil unit; and
a second coil unit,
wherein at least one coil unit of the first coil unit and the second coil unit is configured to rotate about a longitudinal axis.

2. The magnetic resonance coil apparatus of claim 1, wherein the magnetic resonance coil apparatus is configured to rotate at least one coil unit of the first coil unit and the second coil unit about the longitudinal axis to change between an open operating state and a closed operating state.

3. The magnetic resonance coil apparatus of claim 2, wherein in the closed operating state, a larger circular arc of a cylindrical volume is covered by the first coil unit and the second coil unit than in the open operating state.

4. The magnetic resonance coil apparatus of claim 1, further comprising:
a rotation guide configured to rotate the first coil unit and the second coil unit.

5. The magnetic resonance coil apparatus of claim 1, wherein the first coil unit and the second coil unit are arranged concentrically around the longitudinal axis.

6. The magnetic resonance coil apparatus of claim 1, wherein the first coil unit comprises a first cylindrical partial shell, and the second coil unit comprises a second cylindrical partial shell, and
wherein one partial shell of the first partial shell and the second partial shell is arranged internally relative to the other partial shell of the first partial shell and the second partial shell.

7. The magnetic resonance apparatus of claim 6, wherein the internally arranged partial shell comprises an outer surface, and the other partial shell comprises an inner surface,
wherein in an open operating state in an overlapping area of the first partial shell and the second partial shell, the outer surface of the internally arranged partial shell is arranged in parallel with the inner surface of the other partial shell.

8. The magnetic resonance coil apparatus of claim 6, wherein the internally arranged partial shell comprises an outside diameter, and the other partial shell comprises an inside diameter, and
wherein the outside diameter is at most as large as the inside diameter.

9. The magnetic resonance coil apparatus of claim 1, wherein the first coil unit and the second coil unit are configured, in a closed operating state, to cause an interlock of the first coil unit and the second coil unit by a relative movement between the first coil unit and the second coil unit in a direction of the longitudinal axis.

10. The magnetic resonance coil apparatus of claim 9, wherein the magnetic resonance coil apparatus is configured, with the interlock of the first coil unit and the second coil unit, to establish an electrical, mechanical, or electrical and mechanical connection between the first coil unit and the second coil unit.

11. The magnetic resonance coil apparatus of claim 9, further comprising a linear guide unit for the relative movement of the first coil unit and the second coil unit in the direction of the longitudinal axis.

12. The magnetic resonance coil apparatus of claim 1, wherein the first coil unit and the second coil unit comprise connecting elements configured to mechanically, electrically, or mechanically and electrically connect the first coil unit and the second coil unit.

13. The magnetic resonance coil apparatus of claim 12, wherein the connecting elements are configured to be annular and are arranged on ends of the first coil unit and the second coil unit, respectively, in the direction of the longitudinal axis.

14. The magnetic resonance coil apparatus of claim 1, wherein the first coil unit comprises at least one RF coil, the second coil unit comprises at least one RF coil, or the first coil unit and the second coil unit both comprise at least one RF coil.

15. A magnetic resonance apparatus comprising:
a magnetic resonance coil apparatus comprising:
a first coil unit; and
a second coil unit,
wherein at least one coil unit of the first coil unit and the second coil unit is configured to rotate about a longitudinal axis.

16. The magnetic resonance apparatus of claim 15, wherein the magnetic resonance apparatus is configured to arrange one coil unit of the first coil unit and the second coil unit in a fixed-location manner.

17. A method for handling a magnetic resonance coil apparatus comprising a first coil unit and a second coil unit, the method comprising:
positioning an examination object in a receiving zone of the magnetic resonance coil apparatus in an open operating state;
rotating at least one coil unit of the first coil unit and the second coil unit into a closed operating state; and
moving at least one coil unit of the first coil unit and the second coil unit linearly to interlock the first coil unit and the second coil unit.
